(19) United States
(12) Patent Application Publication
(10) Pub. No.: US 2018/0011562 A1
(43) Pub. Date: Jan. 11, 2018

(54) TOUCH DISPLAY PANEL AND METHOD FOR MANUFACTURING THE SAME

(71) Applicant: EverDisplay Optronics (Shanghai) Limited, Shanghai (CN)

(72) Inventors: YU-CHEN WU, Shanghai (CN); Wei Sheng SU, Shanghai (CN); Fengchao YU, Shanghai (CN); Jr-Hong CHEN, Shanghai (CN)

(73) Assignee: EverDisplay Optronics (Shanghai) Limited, Shanghai (CN)

(21) Appl. No.: 15/429,322

(22) Filed: Feb. 10, 2017

(30) Foreign Application Priority Data
Jul. 5, 2016 (CN) 201610520029.1

(51) Int. Cl. G06F 3/041; H01L 51/52; H01L 27/32; H01L 51/00; G06F 3/044

(52) U.S. Cl. CPC G06F 3/041; H01L 27/323; H01L 51/0097; H01L 51/5253; G06F 3/044; G06F 2203/04111; G06F 2203/04102; G06F 2203/04103; H01L 2251/5338

(57) ABSTRACT

A touch display panel and a method for manufacturing the same are provided. The touch display panel includes a flexible substrate, a light emitting device, an encapsulating film and a touch sensing device. The light emitting device is provided on the flexible substrate. The encapsulation film covers the light emitting device and encapsulates the light emitting device in a sealed space formed by the flexible substrate and the encapsulating film. The touch sensing device is provided on a portion of an outer surface of the encapsulating film and configured to sense an external touch operation. In the present disclosure, the touch sensing device is formed directly on the portion of the outer surface of the encapsulating film, such that the touch sensing device is fixed on the portion of the outer surface of the encapsulating film.

### CROSS REFERENCE

This application is based upon and claims priority to Chinese Patent Application No. 201610520029.1, filed on Jul. 5, 2016, the entire contents thereof are incorporated herein by reference.

### TECHNICAL FIELD

The present disclosure generally relates to the field of display device, and more particularly, to a touch display panel that may prevent creases and peelings of touch sensing devices due to bending of the display panel, and a method for manufacturing the same.

### BACKGROUND

Currently, most commercial available display panels are integrated with a touch function and a display function. Accordingly, display panels with both the touch function and the display function are referred to as touch display panels.

In the related art, a touch display panel generally includes successively, in an upward direction, a display structure 10 for the display function and a touch sensing structure 11 for the touch sensing function. The touch sensing structure 11 is attached to the display structure 10 by an adhesion layer 12 (OCA) between the display structure 10 and the touch sensing structure 11.

Currently, touch display panels are developing to be thin and bendable, and are replacing typical panel display devices and becoming mainstream of the display field. In the above assembling means by attaching touch sensing structure 11 to the display structure 10, the adhesion layer 12 (OCA) is required between the display structure 10 and the touch sensing structure 11, thereby increasing the thickness of the touch display panel and being against the slimming demand of the touch display panel. In addition, peelings or creases may occur in the adhesion layer (OCA) after multiple bends, and thus may cause problems such as short lifespan and bad display effect of the touch display panel. Accordingly, the above assembling means is not suitable for free-bendable touch display panels.

It should be noted that, information disclosed in the above background portion is provided only for better understanding of the background of the present disclosure, and thus it may contain information that does not form the prior art known by those ordinary skilled in the art.

### SUMMARY

According to one aspect of the present disclosure, there is provided a touch display panel including a flexible substrate, a light emitting device, an encapsulating film and a touch sensing device. The light emitting device is provided on the flexible substrate. The encapsulating film covers the light emitting device and encapsulates the light emitting device in a sealed space formed between the flexible substrate and the encapsulating film. The touch sensing device is provided on a portion of an outer surface of the encapsulating film, and is configured to sense an external touch operation. Herein, the touch sensing device is formed directly on the portion of the outer surface of the encapsulating film, such that the touch sensing device is fixed on the portion of the outer surface of the encapsulating film.

According to another aspect of the present disclosure, there is provided a method for manufacturing a touch display panel, the method including:

providing a flexible substrate;

forming a light emitting device on the flexible substrate;

covering the light emitting device with an encapsulating film and encapsulating the light emitting device in a sealed space formed between the flexible substrate and the encapsulating film; and

forming a touch sensing device on a portion of an outer surface of the encapsulating film,

wherein the touch sensing device is formed directly on the portion of the outer surface of the encapsulating film, such that the touch sensing device is fixed on the portion of the outer surface of the encapsulating film.

Other objectives and advantages will be further understood from the technical features set forth in the present disclosure. Hereinafter, detailed descriptions are provided to describe embodiments of the present disclosure with reference to the drawings, such that the above and other objectives, features, and advantages may be more apparent and easily understandable.

This section provides a summary of various implementations or examples of the technology described in the disclosure, and is not a comprehensive disclosure of the full scope or all features of the disclosed technology.

### BRIEF DESCRIPTION OF THE DRAWINGS

The above and other objectives, features and advantages will become more apparent by describing example embodiments of the present disclosure in detail with reference to the drawings.

FIG. 1 is a cross sectional view of a touch display panel in the prior art;

FIG. 2 is a cross sectional view of a touch display panel according to an embodiment of the present disclosure;

FIG. 3 is a structural schematic diagram of a touch sensing device according to an embodiment of the present disclosure;

FIG. 4 is a structural schematic diagram of a touch sensing device according to another embodiment of the present disclosure;

FIG. 5 is a cross sectional view of a touch display panel according to another embodiment of the present disclosure;

FIGS. 6-7 are flow charts of a method for manufacturing a touch display panel according to an embodiment of the present disclosure;

FIG. 8 is a cross sectional view of forming a touch sensing device on an encapsulating film according to an embodiment of the present disclosure; and

FIG. 9 is a cross sectional view of forming a touch sensing device on an encapsulating film according to another embodiment of the present disclosure.

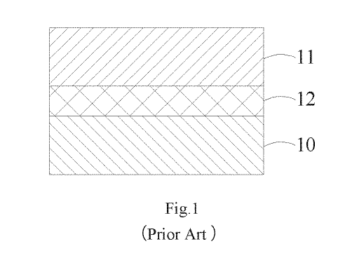

### DETAILED DESCRIPTION

The exemplary implementations will now be described more fully with reference to the accompanying drawings. However, the exemplary implementations may be implemented in various forms and should not be understood as being limited to the implementations set forth herein; rather, these implementations are provided so that this disclosure will be thorough and complete, and will fully convey the conception of exemplary implementations to those skilled in the art. The accompanying drawings are only schematic illustration of the present disclosure, and may be not drawn to scale. In the drawings, the same reference numerals denote the same or similar structures, thus their detailed description will be omitted.

In addition, the features, structures or characteristics described herein can be combined in one or more embodiments in any appropriate way. In the description hereinafter, many specific details are provided for fully understanding of the embodiments of the present disclosure. However, it will be appreciated by those skilled in the art that the technical solution of the present disclosure can be practiced without one or more of the specific details, or with other methods, components, devices or steps, etc. In addition, known structures, methods, devices, implementations, materials or operations will not be illustrated or described in detail, to avoid obscuration of the aspects of the present disclosure.

The above and other technical content, characteristics and effects may be presented clearly in the following detailed description of the embodiments with reference to the drawings. Directional terms, such as upper, lower, left, right, outer, inner, front, rear, or the like, are merely directions with reference to the drawings. Accordingly, the directional terms are illustrative rather than limiting the present disclosure.

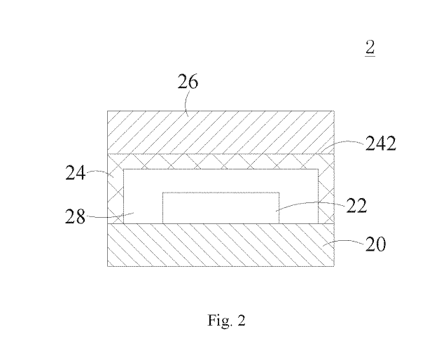

FIG. 2 is a cross sectional view of a touch display panel according to an embodiment of the present disclosure. As illustrated in FIG. 2, the touch display panel 2 may include a flexible substrate 20, a light emitting device 22, an encapsulating film 24 (e.g., tetrafluoroethylene, TFE) and a touch sensing device 26.

The flexible substrate 20 may be formed of a flexible plastic material. However, the present disclosure is not limited thereto, and the flexible substrate 20 may be formed of a metal substrate that is made of stainless steel and a plurality of flexible materials. The flexible substrate is formed of plastic material with excellent thermal resistance and durability, such as at least one of polyethylene ether phthalate, polyvinyl naphthalene, polycarbonate, polyarylester, polyetherimide, polyethersulfone and polyimide.

The light emitting device 22 is provided on the flexible substrate 20. The light emitting device 22 may be an organic light emitting device (OLED).

The encapsulating film 24 (e.g., tetrafluoroethylene, TFE) is formed on the flexible substrate 20 and covers the light emitting device 22. The encapsulating film 24 encapsulates the light emitting device 22 within a sealed space 28 formed between the flexible substrate 20 and the encapsulating film 24. In the present embodiment, the sealed space 28 is a sealed space enclosed by an upper surface 201 of the flexible substrate 20 and an inner surface 241 of the encapsulating film 24. The light emitting device 22 is sealed in the sealed space 28 to prevent the light emitting device 22 from being exposed to the air, which in turn prevents the light emitting device 22 from being damaged by moisture or oxygen in the air. The encapsulating film 24 may be a thin film isolating layer (Barix) developed by Vitex Systems LLC, which has a permeability to moisture and oxygen corresponding to that of a piece of glass. The Barix is formed by laminating polymer films and ceramic films in vacuum atmosphere, and has a total thickness of 3 μm, which is approximately one twentieth of the diameter of human hair. The isolation layer may be provided over the OLED directly, and may isolate and protect the OLED from moisture and oxygen without using other mechanical encapsulating elements. An organic polymer film may be excellent in film forming property, uniformity and surface smoothness but poor in moisture and oxygen isolation property, while an inorganic thin film such as the ceramic film may be excellent in moisture and oxygen isolation property but poor in film forming property and surface smoothness. Accordingly, a complementary moisture and oxygen isolation unit may be formed by alternatively laminating both of them, and the resulted thin film isolation layer may have a total thickness of only 3 μm, thereby satisfying the ultra-slim and ultra-light requirements of the device.

The organic polymer film may be a single layer or laminated layer formed by at least one of polyethylene terephthalate (PET), polyimide, polycarbonate, epoxy resin, polyethylene and polyacrylate. The organic layer may be formed of polyacrylate, and in particular may include a polymer of monomer compositions including a diacrylate-based monomer and a triacrylate-based monomer. A monoacrylate-based monomer may be further included in the monomer compositions. Further, known photoinitiators such as a 2,4,6-trimethylbenzoyl diphenyl phosphoine (TPO) may be further included in the monomer compositions. However, the present disclosure is not limited thereto.

The inorganic thin film may be a single layer or laminated layer including a metal oxide or a metal nitride. In particular, the inorganic layer may include at least one of SiNₓ, Al₂O₃, SiO₂ and TiO₂.

The touch sensing device 26 is formed on an outer surface 242 of the encapsulating film 24 to sense an external touch operation. The touch sensing device 26 may be directly formed on the outer surface 242 of the encapsulating film 24, such that the touch sensing device 26 may be directly fixed on the outer surface 242 of the encapsulating film 24. The touch sensing device 26 may be patterned on the outer surface 242 of the encapsulating film 24 by printing manufacturing process. In order to improve an adhesive power between the touch sensing device 26 and the encapsulating film 24, surface treatments may be performed on the outer surface 242 of the encapsulating film 24 prior to the printing manufacturing process. The surface treatments may include a chemical scheme, a plasma scheme and a layer growth scheme.

The Chemical Scheme

Chemical Vapor Deposition (CVD) refers to a process of introducing gaseous reactors or vapor of liquid reactors containing thin-film-forming elements and other gases required during the reaction into a reaction chamber and forming a thin film on a substrate by chemical reactions at the surface of the substrate. In a super large scale integration circuit, many thin films are formed by CVD. An adherence of the surface treated film may increase by about 30% after the CVD process, thereby preventing scratches due to bending, stretching or the like of the substrate.

The Plasma Scheme

A plasma cleaner, also known as a plasma cleaning machine, a plasma surface modification device, a plasma surface treating device, a plasma etching device, or the like, may be used for the plasma scheme. The plasma cleaner is widely applicable in plasma cleaning, plasma etching, plasma plating, plasma coating, plasma ashing, surface modifying, or the like.

The Layer Growth Scheme

A sputter deposition, generally a magnetically controlled sputter deposition, belongs to a high speed low temperature sputter deposition method.

During the sputter deposition, an inert gas argon (Ar) is provided at a vacuum degree of about 1×10⁻³ Torr (i.e., 1.3×10⁻³ Pa), and a high voltage direct current is applied between a plastic substrate material (an anode electrode) and a metal target material (a cathode electrode). The inert gas is excited by electrons generated by glow discharge between the anode electrode and the cathode electrode to generate a plasma. The plasma bombards out atoms from the metal target material, and the atoms are deposited on the plastic substrate material.

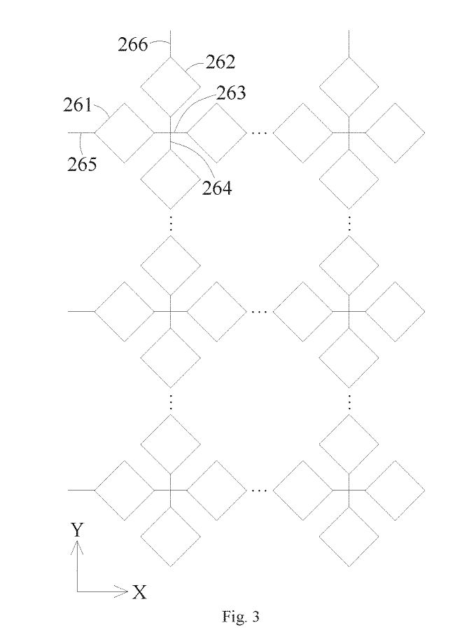

FIG. 3 is a structural schematic diagram of a touch sensing device according to an embodiment of the present disclosure. As illustrated in FIG. 3, the touch sensing device 26 includes a plurality of first sensing pads 261, a plurality of second sensing pads 262, a plurality of first bridge connecting lines 263, a plurality of second bridge connecting lines 264, a first lead 265 and a second lead 266. The first sensing pads 261 are arranged in an X direction, and the second sensing pads 262 are arranged in a Y direction, and the first sensing pads 261 are interleaved with the second sensing pads 262. Each of the first bridge connecting lines 263 bridge connects two adjacent first sensing pads 261. Each of the second bridge connecting lines 264 bridge connects two adjacent second sensing pads 262. An insulation layer is formed between the first bridge connecting line 263 and the second bridge connecting line 264 for dielectric property. The first lead 265 and the second lead 266 are provided at the peripheral of the touch sensing device 26 and connect the first sensing pads 261 and the second sensing pads 262, respectively. The first lead 265 and the second lead 266 are connected to at least one signal output terminal (e.g., a pad of a flexible circuit board), such that a sensed signal of the touch sensing device 26 (such as a capacitive sensor) may be transmitted to a successive signal processing circuit (such as an IC) through the signal output terminal. In the present embodiment, the first bridge connecting lines 263 bridge connecting two adjacent first sensing pads 261 and the second bridge connecting lines 264 bridge connecting two adjacent second sensing pads 262 may be jet printed (spray coated) metal lines formed by printing manufacturing process. Accordingly, the first bridge connecting lines 263 and the second bridge connecting lines 264 may be very thin and visibility of the connecting lines may be greatly reduced, and the connecting lines may be less visible to the user, thereby improving visual effects. Further, as the width (thickness) of the lines may be greatly reduced by using the printing manufacturing process method, an overlapped area of the overlapping first bridge connecting lines 263 and the second bridge connecting lines 264 may be greatly reduced, thereby reducing the parasitic capacitance. Obviously, in the present embodiments, the bridge connecting lines 263 and 264 bridge connecting two adjacent sensing pads are not limited to be formed by printing manufacturing process. For example, one of the bridge connecting lines (e.g., the first bridge connecting lines 263) may be formed by printing manufacturing process, and the other one (e.g., the second bridge connecting lines 264) may be formed simultaneously with the sensing pads by patterning a transparent electrode, e.g., an indium tin oxide (ITO) electrode.

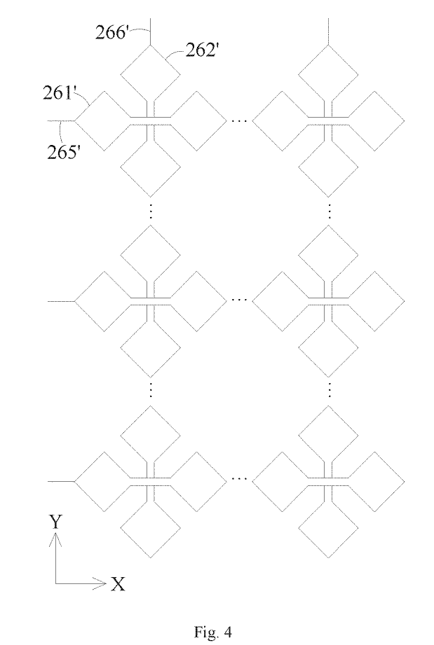

FIG. 4 is a structural schematic diagram of a touch sensing device according to another embodiment of the present disclosure. As illustrated in FIG. 4, the touch sensing device 26′ includes a plurality of first sensing pads 261′, a plurality of second sensing pads 262′, a first lead 265′ and a second lead 266′. The first sensing pads 261′ are arranged in an X direction, and the second sensing pads 262′ are arranged in a Y direction, and the first sensing pads 261′ are interleaved with the second sensing pads 262′. The first lead 265′ and the second lead 266′ are provided at the peripheral of the touch sensing device 26′ and connect the first sensing pads 261′ and the second sensing pads 262′, respectively. The first lead 265′ and the second lead 266′ are connected to at least one signal output terminal (e.g., a pad of a flexible circuit board), such that a sensed signal of the touch sensing device 26′ (such as a capacitive sensor) may be transmitted to a successive signal processing circuit (such as an IC) through the signal output terminal. The present embodiment differs from the above embodiments mainly in that: the present embodiment does not include any bridge connecting lines, and connections between adjacent sensing pads are formed simultaneously with the sensing pads by patterning a transparent electrode.

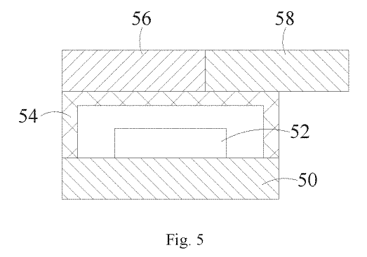

FIG. 5 is a cross sectional view of a touch display panel according to an embodiment of the present disclosure. As illustrated in FIG. 5, the touch display panel 5 may include a flexible substrate 50, a light emitting device 52, an encapsulating film 54 (e.g., TFE), a touch sensing device 56 and a flexible circuit board 58. In the present embodiment, the flexible substrate, the light emitting device, the encapsulating film and the touch sensing device are the same as those disclosed in the above embodiments, and the main distinction between the present embodiment and the above embodiments lies in the flexible circuit board. The flexible circuit board 28 is connected to the first sensing pads and second sensing pads of the touch sensing device through the first and second leads, such that a sensed signal of the touch sensing device may be transmitted to a successive signal processing circuit (such as an IC) through a signal output terminal.

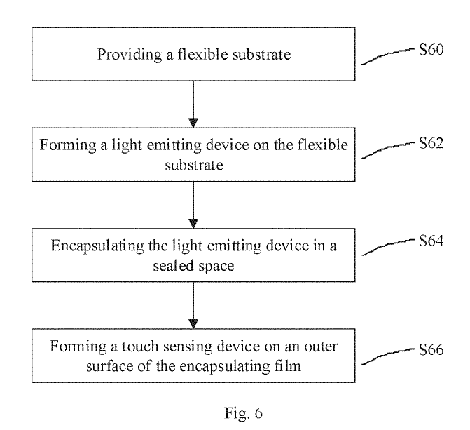

FIG. 6 is a flow chart of a method for manufacturing a touch display panel according to an embodiment of the present disclosure. As illustrated in FIG. 6, the method for manufacturing the touch display panel includes the steps as follows.

In step S60, a flexible substrate is provided.

In step S62, a light emitting device is formed on the flexible substrate.

In step S64, an encapsulating film is formed on the light emitting device to encapsulate the light emitting device in a sealed space formed between the flexible substrate and the encapsulating film.

In step S66, a touch sensing device is formed on an outer surface of the encapsulating film. In the present embodiment, the touch sensing device is formed directly on the outer surface of the encapsulating film, and the touch sensing device is fixed on the outer surface of the encapsulating film.

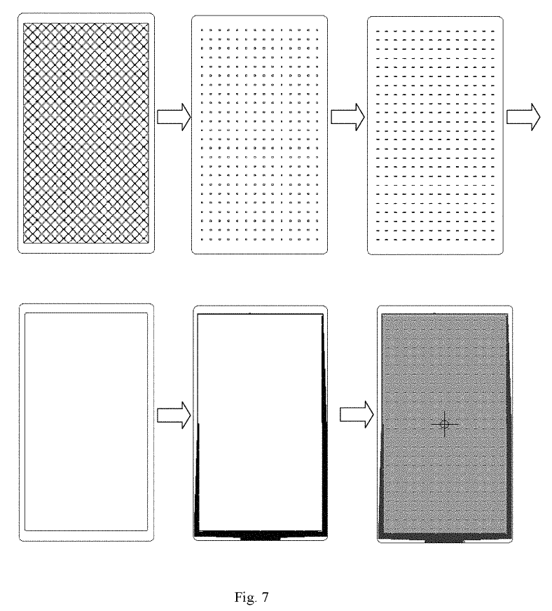

As illustrated in FIG. 7, in one embodiment, the step S66 may include the steps as follows.

A touch sensing layer is formed on the outer surface of the encapsulating film. Before forming the touch sensing layer on the outer surface of the encapsulating film, the outer surface of the encapsulating film may be surface treated by a chemical scheme, a plasma scheme, or a layer growth scheme, to improve an adhesive power between the touch sensing layer and the encapsulating film. The touch sensing layer may be formed directly on the outer surface of the encapsulating film by printing manufacturing process, so as to form patterned first sensing pads and second sensing pads on the outer surface of the encapsulating film. The touch sensing layer may be formed of transparent metal oxides such as ITO, indium zinc oxide (IZO), aluminium zinc oxide (AZO), gallium zinc oxide (GZO) or the like, or may be formed of conductive materials such as silver nanowire. However, the present disclosure is not limited thereto.

An insulation layer is formed on the touch sensing layer. The insulation layer is formed on the touch sensing layer by printing manufacturing process. The insulation layer covers the first sensing pads and the second sensing pads of the touch sensing layer. The insulation layer may be formed of resin material, silicon oxide, silicon nitride, or the like.

A bridge connecting line is formed on the insulation layer. Corresponding connection holes may be formed in the insulation layer at positions corresponding to two adjacent second sensing pads, by for example etching process, such that the bridge connecting line formed on the insulation layer may connect the adjacent second sensing pads. The bridge connecting line may be formed on the insulation layer at the position corresponding to the two adjacent second sensing pads to be connected by printing manufacturing process. The bridge connecting line may be formed of a conductive material such as ITO, Mo, Al, Cu or the like.

A protection layer is formed on the touch sensing layer and the bridge connecting line. The protection layer may be formed by printing manufacturing process. The protection layer may cover the touch sensing layer and the bridge connecting line to protect the touch sensing layer and the bridge connecting line. The protection layer may be formed of the same material as that of the above insulation layer, e.g., may be formed of resin material, silicon oxide, silicon nitride, or the like.

A lead is formed on the touch sensing layer. The lead may be formed by printing manufacturing process. The lead is connected to the first sensing pads and the second sensing pads of the touch sensing layer, respectively. By connecting the other end of the lead to a signal output terminal of the flexible circuit board, the sensed signal of the touch sensing device may be transmitted to successive signal processing IC for corresponding touch sensing operation. The lead may be formed of transparent metal oxide (e.g., ITO, IZO, AZO, GZO or the like), conductive high polymer material (e.g., PEDOT:PSS), nanotechnology material (e.g., sliver nanowire), carbon nanotube, or the like.

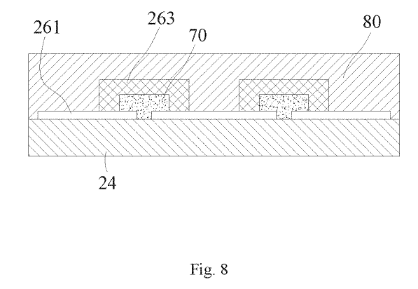

After the above steps, the touch sensing device may be formed directly on the outer surface of the encapsulating film. FIG. 8 illustrates a cross sectional view of forming a touch sensing device on an outer surface of an encapsulating film using the above steps. As illustrated in FIG. 8, a plurality of first sensing pads 261 are formed on an encapsulating film 24. The plurality of first sensing pads 261 are insulated from second sensing pads 262 (not illustrated) by an insulation layer 70. A first bridge connecting line 263 is covered on the insulating layer 70, and the plurality of first sensing pads 261 are electrically connected by the first bridge connecting line 263. A protection layer 80 covers the first sensing pads 261 and the first bridge connecting line 263.

The present disclosure, as being compared with bonding the touch sensing device and the display unit using the adhesion layer (OCD) in the prior art, excludes the use of the adhesion layer (OCD), such that the total thickness of the touch display panel becomes thinner. In addition, a subsequent aligning step during the connection process of the touch sensing device and the display unit is unnecessary, thereby simplifying the manufacture process. Further, problems such as creases and peelings of the touch sensing device formed on the encapsulating film due to bending of the panel may be prevented, and thus the present disclosure may be suitable for bendable touch display panels.

In another embodiment, the step S66 may further includes the steps as follows. A touch sensing layer is formed on the outer surface of the encapsulating film. Before forming the touch sensing layer on the outer surface of the encapsulating film, the outer surface of the encapsulating film may be surface treated by a chemical scheme, a plasma scheme, or a layer growth scheme, to improve an adhesive power between the touch sensing layer and the encapsulating film. The touch sensing layer may be formed directly on the outer surface of the encapsulating film by printing manufacturing process, so as to form patterned first sensing pads and second sensing pads on the outer surface of the encapsulating film. The touch sensing layer may be formed of transparent metal oxides such as ITO, IZO, AZO, GZO or the like, or may be formed of conductive materials such as silver nanowire. In the present embodiment, patterned connection are formed between the first sensing pads and between the second sensing pads formed on the outer surface of the encapsulating film. Compared with the above embodiments, the present embodiment may exclude the steps of forming bridge connecting lines for connections of the corresponding sensing pads.

A protection layer is formed on the touch sensing layer. The protection layer may be formed by printing manufacturing process. The protection layer may cover the touch sensing layer to protect the touch sensing layer. The protection layer may be formed of resin material, silicon oxide, silicon nitride, or the like.

A lead is formed on the touch sensing layer. The lead may be formed by printing manufacturing process. The lead is connected to the first sensing pads and the second sensing pads of the touch sensing layer, respectively. By connecting the other end of the lead to a signal output terminal of the flexible circuit board, the sensed signal of the touch sensing device may be transmitted to successive signal processing IC for corresponding touch sensing operation. The lead may be formed of transparent metal oxide (e.g., ITO, IZO, AZO, GZO or the like), conductive high polymer material (e.g., PEDOT:PSS), nanotechnology material (e.g., sliver nanowire), carbon nanotube, or the like.

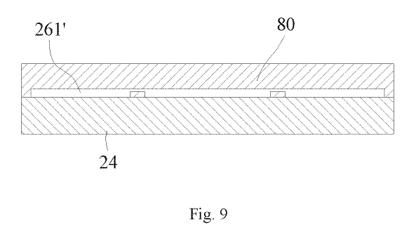

After the above steps, the touch sensing device may be formed directly on the outer surface of the encapsulating film. FIG. 9 is a cross sectional view of forming a touch sensing device on an outer surface of an encapsulating film using the above steps. As illustrated in FIG. 9, a plurality of first sensing pads 261′ are formed on an encapsulating film 24, and the first sensing pads 261′ are covered by a protection layer 80.

Compared with the above embodiment, by forming the touch sensing device directly on the outer surface of the encapsulating film using the above steps, a step for forming bridge connecting lines may be excluded from the forming process of the touch sensing device, thereby simplifying a process for forming the touch sensing device on the encapsulating film.

Hereinabove, exemplary embodiments of the present disclosure have been illustrated and described in detail. It should be appreciated that the present disclosure is not limited to the detailed structures, arrangements or implementations described herein. Rather, the present disclosure intends to cover various modifications and equivalent arrangements included in the spirit and scope of the claims.

What is claimed is:

1. A touch display panel comprising:
a flexible substrate;
a light emitting device provided on the flexible substrate;
an encapsulating film disposed to cover the light emitting device and encapsulate the light emitting device in a sealed space formed by the flexible substrate and the encapsulating film; and
a touch sensing device provided on a portion of an outer surface of the encapsulating film and configured to sense an external touch operation,
wherein the touch sensing device is formed directly on the portion of the outer surface of the encapsulating film, such that the touch sensing device is fixed on the portion of the outer surface of the encapsulating film.

2. The touch display panel according to claim 1, wherein the touch sensing device is patterned on the portion of the outer surface of the encapsulating film.

3. The touch display panel according to claim 2, wherein the touch sensing device is patterned on the portion of the outer surface of the encapsulating film by printing manufacturing process.

4. The touch display panel according to claim 1, further comprising a flexible circuit board, wherein:
the touch sensing device comprises a plurality of first sensing pads, a plurality of second sensing pads, a first bridge connecting line, a second bridge connecting line, a first lead and a second lead;
each of the plurality of first sensing pads is interleaved with each of the plurality of second sensing pads;
the plurality of first sensing pads are electrically connected together by the first bridge connecting line, and are connected to the flexible circuit board via the first lead;
the plurality of second sensing pads are electrically connected together by the second bridge connecting line, and are connected to the flexible circuit board via the second lead; and
the first bridge connecting line is insulated from the second bridge connecting line.

5. The touch display panel according to claim 1, further comprising a flexible circuit board, wherein:
the touch sensing device comprises a plurality of first sensing pads, a plurality of second sensing pads, a first lead and a second lead;
the plurality of first sensing pads are connected to the flexible circuit board via the first lead;
each of the plurality of first sensing pads is interleaved with each of the plurality of second sensing pads;
the plurality of second sensing pads are connected to the flexible circuit board via the second lead; and
the first sensing pads are insulated from the second sensing pads.

6. A method for manufacturing a touch display panel comprising:
providing a flexible substrate;
forming a light emitting device on the flexible substrate;
covering the light emitting device with an encapsulating film and encapsulating the light emitting device in a sealed space formed between the flexible substrate and the encapsulating film; and
forming a touch sensing device directly on a portion of an outer surface of the encapsulating film to fix the touch sensing device on the portion of the outer surface of the encapsulating film.

7. The method according to claim 6, wherein before the step of forming a touch sensing device directly on a portion of an outer surface of the encapsulating film, the method further comprises:
performing surface treatment on the outer surface of the encapsulating film to improve an adhesive power between the touch sensing device and the encapsulating film.

8. The method according to claim 6, wherein the touch sensing device is patterned on the portion of the outer surface of the encapsulating film.

9. The method according to claim 6, wherein the step of forming a touch sensing device on a portion of an outer surface of the encapsulating film comprises:
forming a touch sensing layer on the portion of the outer surface of the encapsulating film;
forming an insulation layer on the touch sensing layer;
forming a bridge connecting line on the insulation layer;
forming a protection layer on the touch sensing layer and the bridge connecting line; and
forming a lead on the touch sensing layer.

10. The method according to claim 6, wherein the step of forming a touch sensing device on a portion of an outer surface of the encapsulating film comprises:
forming a touch sensing layer on the outer surface of the encapsulating film;
forming a protection layer on the touch sensing layer; and
forming a lead on the touch sensing layer.
